(19) United States
(12) Patent Application Publication
(10) Pub. No.: US 2026/0025115 A1
(43) Pub. Date: Jan. 22, 2026

(54) METHOD AND APPARATUS FOR AUTOMATIC GAIN CONTROL

(71) Applicant: Renesas Electronics America Inc., Milpitas, CA (US)

(72) Inventors: Kaloyan Diyanov DANAILOV, Varna (BG); Iliya Hristomilov PARTENOV, Varna (BG)

(73) Assignee: Renesas Electronics America Inc., Milpitas, CA (US)

(21) Appl. No.: 18/779,581

(22) Filed: Jul. 22, 2024

(51) Int. Cl. H03G 3/30; G01B 7/30; H03B 19/00

(52) U.S. Cl. CPC H03G 3/3052; G01B 7/30; H03B 19/00

(57) ABSTRACT

Apparatus and methods for gain control of a circuit for measuring a parameter are provided. The apparatus includes a sinewave generator module and a gain control signal generator module. The sinewave generator module is configured to receive a first signal and a second signal. The first signal is proportional to a sinusoid of a measured parameter and the second signal corresponds to the first signal shifted by a quarter of a period of the sinusoid. The sinewave generator module is further configured to generate an approximated sinusoidal function over time by determining values of a shifted sine function with a first frequency at a plurality of sampling points. A phase shift and an amplitude of the shifted sine function are based on the first signal and second signal.

### TECHNICAL FIELD

The present disclosure relates to automatic gain control and more particular to automatic gain control methods and devices for sensor circuits.

### BACKGROUND

Automatic Gain Control (AGC) is a critical component in the realm of sensor circuits, designed to maintain consistent output signal levels despite variations in input signal strength.

The development and implementation of AGC systems address the challenges posed by fluctuating signal conditions, which are inherent in many sensor-based applications. This technology ensures that the output signal remains within a desired amplitude range, thereby enhancing the reliability and accuracy of the sensor's performance.

The primary goal of AGC is to enhance the reliability and accuracy of sensor measurements by compensating for variations that could otherwise lead to signal distortion or data loss. By automatically regulating the gain, AGC helps in optimizing the signal-to-noise ratio (SNR), thereby improving the clarity and quality of the sensor's output.

One particular sensor of interest for AGC is a differential transformer, for which the output signal has an amplitude indicative if the measured quantity.

Differential transformers, such as Linear Variable Differential Transformers (LVDTs) and Rotary Variable Differential Transformers (RVDTs), are widely used in precision measurement applications due to their high accuracy and reliability in sensing linear and angular displacement, respectively. Both LVDTs and RVDTs operate on the principle of electromagnetic induction, converting mechanical movement into an electrical signal that can be precisely measured. However, the output signals from these devices can vary significantly due to changes in excitation voltage, temperature fluctuations, or mechanical variations. To address these challenges and enhance the performance of LVDTs and RVDTs, Automatic Gain Control (AGC) is employed.

In an LVDT, a primary coil is energized with an AC excitation voltage, creating a magnetic field that induces a voltage in two secondary coils. The position of the movable core within the transformer affects the differential voltage between the secondary coils, which is then used to determine the displacement. Similarly, in an RVDT, the angular position of a rotating core alters the magnetic coupling between the primary and secondary windings, producing a differential voltage proportional to the angular displacement.

AGC in the context of differential transformers aims to maintain a constant amplitude of the differential output signal, ensuring accurate position or angle measurements regardless of variations in the excitation voltage or other environmental conditions. This is typically achieved by dynamically adjusting the gain of the signal conditioning circuitry that processes the LVDT or RVDT output.

LVDTs and RVDTs can be enhanced in performance and accuracy by employing receiver coils wound in sine and cosine patterns. These specialized configurations are particularly effective in applications requiring high precision and sensitivity, such as in angular displacement measurements. By leveraging the unique properties of sinusoidal and cosinusoidal windings, these transformers can achieve improved signal quality and resolution.

FIGS. 1A and B depict nonlimiting example configurations for an LVDT and an RVDT with sinusoidal and cosinusoidal windings. The VDT comprises a sine receiver coil 2 and a cosine receiver coil 3, each having one positive and one negative period. The sine receiver coil 2 and the cosine receiver coil 4 are surrounded by a transmitter coil 4.

In the LVDT, the coils 2, 3, 4 are arranged along a linear path to detect a linear motion of a target 8. In the RVDT, the coils 2, 3, 4 are arranged circularly for detecting a rotary motion of the target 8. The target 8 can be any kind of metal, such as aluminum, steel, or a printed circuit board (PCB) with a printed copper layer.

As example, FIG. 2A depicts the output signal of the sine receiver coil 2 for the RVDT configuration. The transmitter coil 4 is energized with a high frequency AC voltage (excitation signal), e.g., A*sin(wt), wherein A is the amplitude of the AC voltage and w the angular frequency.

By energizing the transmitter coil 4 with high frequency AC voltage, a magnetic field is generated that interacts with the target 8. The movement of the target 8 through the magnetic field induces a voltage in the sine and cosine receiver coils 2 and 3. To be precise, the output signal at the receiver coils correspond to an amplitude modulation of the transmitter coil signal, wherein the amplitude is directly proportional to the measured quantity. In the example of FIG. 2A, the amplitude of the sine receiver coil 2 output signal of the RVDT is direct proportional to the sin(ϕ), wherein ϕ is the angular displacement of the target 8.

For measuring the measured quantity, the output signals are demodulated. An example for the demodulated signals for an RVDT is depicted in FIG. 2B. The demodulated signals may be analog signals. The demodulated signals of the sine and cosine receiver coils 3, 4 are proportional to the measured quantity, e.g., the angle. As the demodulated signal may not only depend on the amplitude of the excitation signal of the transmitter coil 4, but also on properties of the target, the demodulated signals may vary over a large value range. Therefore, AGC is used to adjust the gain of the output signals of the receiver coils in order to be in a desired value range, e.g., a value range optimal for circuit elements used for demodulation, or analog to digital conversion.

An example for such a circuit is depicted FIG. 3. Sensor 10 may be an LVDT or an RVDT as described above. The LC oscillator generates the excitation signal for the transmitter coil 4. The modulated output signals of the two receiver coils are gain controlled via a Programmable Gain Amplifier (PGA), which is controlled based on a signal from AGC 100. The gain adjusted output signals are then demodulated by a synchronous demodulator to output the signals as shown in FIG. 2B. These signals are also the input for AGC 100.

To adjust the value range, AGC 100 determines an amplitude of the input signal and provides a corresponding control signal for the PGA. In particular, AGC 100 determines the amplitude of the signal by determining the squared sum of the demodulated signals of the two receiver coils. Performing these non-linear mathematic operations in the analog domain is however complex and is prone to inaccuracies due to process variations and temperature drifts. It is therefore an aim of the present invention to improve the efficiency and accuracy of amplitude determination for AGC.

The amplitude determined by AGC 100 circuit is then compared to a threshold. Depending on the outcome, a digital signal is incremented or decremented. This digital signal is then fed to the PGA in order to apply the appropriate gain to the output signal of the two receiver coils. As the digital signal is inherently discrete, jumps are caused in the output signal of the receiver coils when the gain changes. Further, multiple gain steps are needed to adjust the gain in the PGA. This may increase the complexity of the PGA and also increases the circuit area needed for the PGA. It is therefore an aim of the present invention to improve the efficiency of applying the gain to the output signals of the receiver coils.

### SUMMARY

In view of the above, the present disclosure provides an apparatus and a method for automatic gain control, having the features of the respective independent claims.

According to a first aspect of the disclosure, an apparatus for automatic gain control is provided. The apparatus may include a sinewave generator module and a gain control signal generator module. The sinewave generator module may be configured to receive a first signal and a second signal. The first and the second signal may be analog signals and may correspond to voltages. The first signal may be proportional to a sinusoid of a measured parameter (e.g., a measured angle or a measured linear translation parameter) and the second signal may correspond to the first signal shifted by a quarter of a period of the sinusoid. The sinewave generator module may be further configured to generate an approximated sinusoidal function over time by determining values of a shifted sine function with a first frequency at a plurality of sampling points. A phase shift and an amplitude of the shifted sine function may be based on the first signal and second signal. The approximated sinusoidal function over time may be a step function. The sinewave generator module may be configured to perform linear operations in the analog domain. Further, the gain control signal generator module may be configured to generate a third signal that is proportional to an amplitude spectrum of the approximated sinusoidal function at the first frequency. The first frequency may correspond to a first harmonic of the approximated sinusoidal function. The third signal may be an analog signal and may correspond to a voltage. The third signal may be proportional to an amplitude/scaling factor in the first signal and second signal. The gain control signal generator module may be further configured to output the third signal to a circuit for measuring the measured parameter. The apparatus for automatic gain control may be connected to the circuit and the third signal may be used for gain control of the circuit.

By determining the third signal, which is proportional to an amplitude/scaling factor of the first and second signal, based on linear operations in the analog domain, automatic gain control can be implemented with a reduced complexity and improved accuracy.

In some embodiments, the first signal may be proportional to sin(x) and the second signal may be proportional to cos(x), wherein x may be the measured parameter. In particular, the first signal may be equal to A*sin(x) and the second signal may be equal to A*cos(x). Amplitude/scaling factor A may depend on an excitation signal for the circuit for measuring the measured parameter and a sensor configuration for measuring the measured parameter.

In some embodiments, determining values of the shifted sine function with a first frequency at a plurality of sampling points may include, for each value and a corresponding sampling point, to configure the sinewave generator module to summate weighted versions of the first signal and the second signal. Weights of the weighted versions of the first and the second signal may correspond to a sine function and cosine function evaluated at a first angle, wherein the first angle may be based on the sampling point and the first frequency. The weights may be

$$1 , \frac{\sqrt{3}}{2} and \frac{1}{2} .$$

In some embodiments, the sinewave generator module may include a multiplexing module and a summation module. The multiplexing module may be configured to determine a plurality of fourth signals by multiplexing positive and negative versions of the first signal and the second signal, and a zero signal. The summation module may be configured to multiply each of the plurality of fourth signals with a different weight of the weights to generate weighted versions of the plurality of fourth signals. The summation module may be further configured to summate the weighted versions of the plurality of fourth signals to generate a value of the shifted sine function at the sampling point. The plurality of fourth signals and weights for each of the plurality of fourth signals may be chosen for each sampling point such that the shifted sine function with the first frequency and with an amplitude of A is approximated. The summation module may be an analog summator. The multiplexing module may include a plurality of digitally controlled multiplexers configured to multiplex the positive and negative versions of the first signal and the second signal, and the zero signal. Further, the sampling points may be determined based on a clock signal having a second frequency. The second frequency may be at least twice as high as the first frequency.

In some embodiments, a number of the plurality of fourth signals is 1 or 2. In other words, the multiplexing module may include three multiplexers and for each sampling point, only one or two out of the three multiplexers output a non-zero signal.

In some embodiments, the sinewave generator module may further include a smoothing module. The smoothing module may be configured to generate a sinusoidal function over time by smoothing the approximated sinusoidal function. Further, the gain control signal generator module may include an AC-DC converter module. The AC-DC converter module may be configured to generate the third signal from the sinusoidal function. The AC-DC converter module may include a rectifier and a first low-pass filter. The rectifier may be a full-wave rectifier or a half-wave rectifier. For the full-wave rectifier, third signal may be equal to

$$A * \frac{2}{π} ,$$

and for the half-wave rectifier, the third sign al may be equal to A/π.

In some embodiments, the smoothing module may include a second low-pass filter configured to generate the sinusoidal function over time by filtering the approximated sinusoidal function. A cut-off frequency of the second low-pass filter may correspond to or may be close to the first frequency. In other words, the second low-pass filter may be suitable for filtering out frequencies of the approximated sinewave function over time other than a first harmonic.

In some embodiments, the smoothing module may further comprise a high-pass filter. The high-pass filter may be configured to operate together with the second low-pass filter to generate the sinusoidal function over time by smoothing the approximated sinusoidal function. A cut-off frequency of the high-pass filter may correspond to or may be close to the first frequency.

By using a high-pass filter in addition to the second-low pass filter, temperature induced drifts of the cut of frequencies of these filters may have a reduced effect on the accuracy of the determined third signal.

In some embodiments, the apparatus may further include a drift adaptation module. The drift adaptation module may be configured to adapt the first frequency to match a temperature induced drift of the cut-off frequency of the second low-pass filter or/and the high-pass filter.

By adapting the first frequency in a direction of the cut-off frequency drift, accuracy of the determined third signal may be further improved over a certain temperature range.

In some embodiments, the gain control signal generator module may include an error signal generator module. The error signal generator module may be configured to generate an error signal by comparing the third signal to a first reference value. The first reference value may be a reference voltage. The reference voltage may be based on a desired signal range for the first signal and the second signal. The error signal generator module may be further configured to output the error signal to the circuit for measuring the measured parameter, wherein the error signal is used for gain control of the circuit.

In some embodiments, using the error signal for gain control of the circuit for measuring the measured parameter may include controlling an LC oscillator with the error signal, wherein the LC oscillator is part of the circuit for measuring the measured parameter and configured to provide an excitation signal.

In some embodiments, using the error signal for gain control of the circuit for measuring the measured parameter may include controlling an analog gain element in the circuit for measuring the measured parameter with the error signal. The analog gain element may be positioned in a signal chain of the measured parameter. The signal chain may be a high frequency signal chain or a low frequency chain. The frequency of the high frequency signal chain may correspond to a frequency of an excitation signal for measuring the measured parameter. The analog gain element may be an attenuator.

By providing an analog gain control via the LC oscillator or an analog gain element in the signal chain of the measured parameter, jumps in the first signal and the second signal may be avoided. In other words, output signals of the circuit for measuring the measured parameter may be more stable.

In some embodiments, the apparatus may further include an LC calibration module. The LC calibration module may be configured to calibrate an LC oscillator based on the third signal.

The LC oscillator may provide an excitation signal for the circuit for measuring the measured parameter. Calibration of the LC oscillator may be performed at startup of the circuit to adapt the circuit for a sensor used for measuring the measured parameter, in particular, when the LC calibration module, the sinewave generator module and the gain control signal generator module share the same resources.

In some embodiments, the LC calibration module may include a comparison module and a digital output module. The comparison module may be configured to compare the third signal to a second reference value. The second reference value may be a reference voltage. Based on a result of the comparison, the digital output module may be configured to increment or decrement a digital signal. The digital output module may be further configured to output the digital signal for controlling the LC oscillator.

According to a second aspect of the disclosure, a measurement circuit with automatic gain control is provided. The measurement circuit with automatic gain control may include the apparatus for automatic gain control according to any embodiment of the first aspect. The measurement circuit with automatic gain control may further include a circuit for measuring a measured parameter. The circuit may be connected to the apparatus for automatic gain control. In other words, the circuit for measuring a measured parameter may output signals indicative of the measured parameter, which may be the input for the apparatus for automatic gain control. The apparatus for automatic gain control may provide a gain control signal for the circuit for measuring a measured parameter.

In some embodiments, the circuit may be a circuit for a variable differential transformer. The variable differential transformer may be a linear variable differential transformer or a rotary variable differential transformer. The differential transformer may include a transmission coil und two receiver coils. Windings of the two receiver coils may be shaped as a sinusoid such that a first output signal of a first receiver coil may be related to a sinus of the measurement parameter and a second output signal of a second receiver coil may be related to a cosine of the measurement parameter. The first output signal and the second output signal may be generated based on a high frequency excitation signal input to the transmission coil.

In some embodiments, the first signal may correspond to a demodulated first output signal and the second signal may correspond to a demodulated second output signal. Demodulation of the first output signal and the second output signal may be performed by a synchronous demodulator.

According to a third aspect of the disclosure, a method for automatic gain control is provided. The method performing gain control with an apparatus according to any embodiment of the first aspect.

It will be appreciated that apparatus features and method steps may be interchanged in many ways. In particular, the details of the disclosed method(s) can be realized by the corresponding apparatus (or system), and vice versa, as the skilled person will appreciate. Moreover, any of the above statements made with respect to the method(s) are understood to likewise apply to the corresponding apparatus (or system), and vice versa.

### BRIEF DESCRIPTION OF DRAWINGS

Example embodiments of the disclosure are explained below with reference to the accompanying drawings, wherein

FIGS. 1A and 1B illustrate differential transformers based on sine and cosine shaped receiver coils for measuring a linear translation and an angle, respectively,

FIG. 2A depicts the modulated output signal of sine shaped receiver coil of a differential transformer,

FIG. 2B depicts the demodulated output signals of a sine shaped and a cosine shaped receiver coil of a differential transformer,

FIG. 3 schematically illustrates an automatic gain control circuit and a gain-controlled sensor circuit according to the prior art,

FIG. 4 schematically illustrates an automatic gain control circuit according to embodiments of the disclosure,

FIG. 5 schematically illustrates a first implementation of the automatic gain control circuit and a gain-controlled sensor circuit according to embodiments of the disclosure,

FIG. 6 schematically illustrates the generation of the approximated sinewave function over time according to embodiments of the disclosure,

FIG. 7 schematically illustrates an example implementation for generating the approximated sinewave function over time according to embodiments of the disclosure,

FIG. 8 schematically illustrates a second implementation of the automatic gain control circuit and a gain-controlled sensor circuit according to embodiments of the disclosure,

FIG. 9 schematically illustrates a temperate induced shift of cut-off frequencies of a low-pass and a high-pass filter and a shifting of the first harmonic approximated sinewave function over time, and

FIG. 10 is a flowchart illustrating an example of a method for automatic gain control according to embodiments of the disclosure.

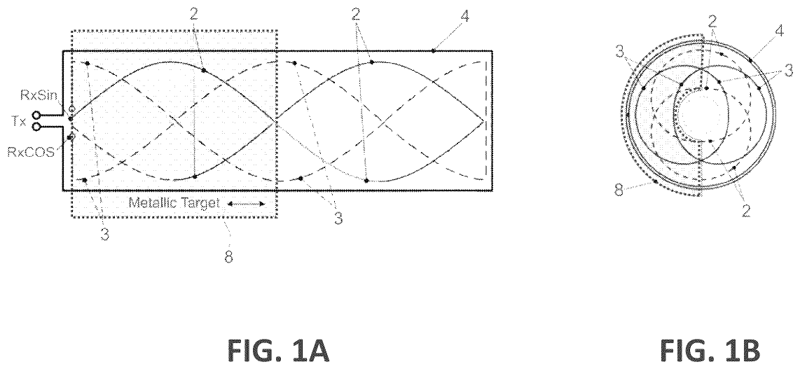

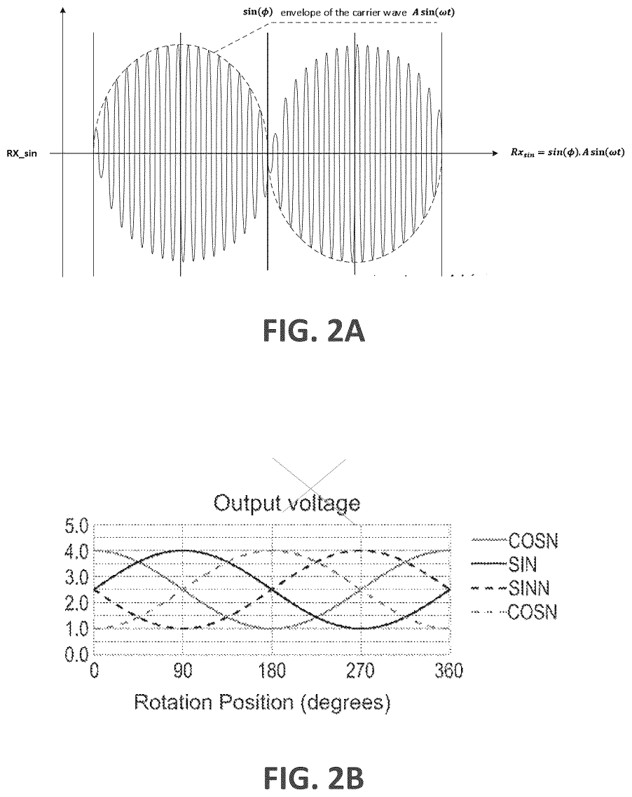

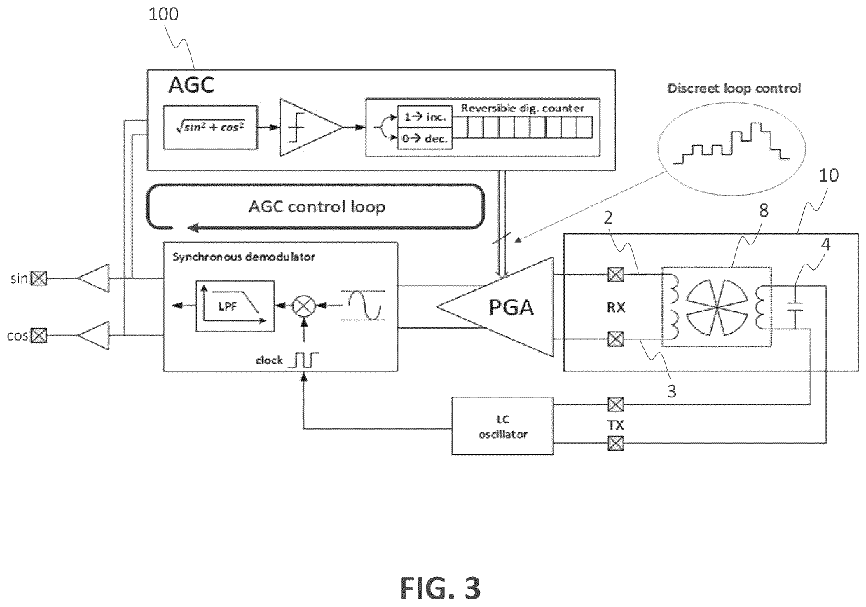

### DETAILED DESCRIPTION

The Figures (FIGs.) and the following description relate to preferred embodiments by way of illustration only. It should be noted that from the following discussion, alternative embodiments of the structures and methods disclosed herein will be readily recognized as viable alternatives that may be employed without departing from the principles of what is claimed.

Reference will now be made in detail to several embodiments, examples of which are illustrated in the accompanying figures. It is noted that wherever practicable similar or like reference numbers may be used in the figures and may indicate similar or like functionality. The figures depict embodiments of the disclosed apparatus (or method) for purposes of illustration only. One skilled in the art will readily recognize from the following description that alternative embodiments of the structures and methods illustrated herein may be employed without departing from the principles described herein.

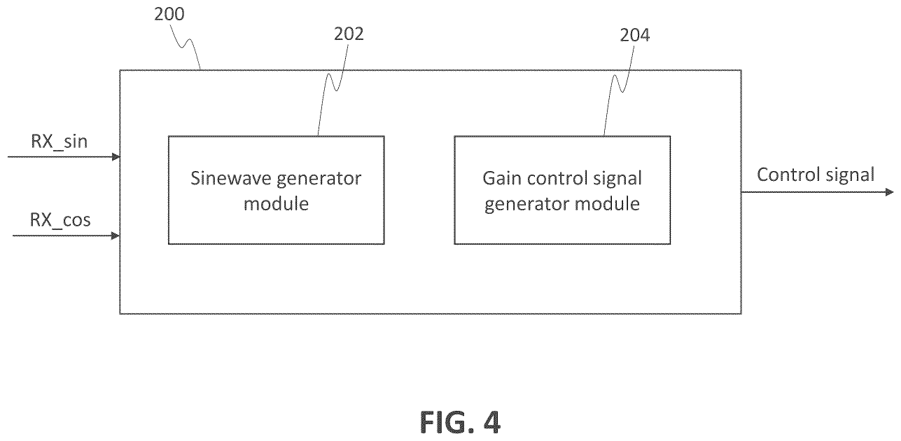

The general idea of the invention is schematically depicted in FIG. 4. In FIG. 4, AGC 200 may receive the demodulated signals of the two receiver coils (RX_sin, RX_cos). The demodulated signals may be analog signals. The demodulated signals may further correspond to voltages. More generally, AGC 200 may receive a first signal that is proportional to a sine of a measured parameter, e.g., an angle or a linear translation parameter. AGC 200 may further receive a second signal that corresponds to the first signal shifted by quarter a period of the first signal (e.g., shifted in phase by) 90°, i.e. a signal that is proportional to a cosine of the measured parameter.

While the input signals have been previously described with reference to a differential transformer, the description should not be construed to limit the invention to this particular sensor type or generally to sensors. As long as the output of a circuit, device, or system is indicative of a sine/cosine of a parameter, AGC 200 may be used to control the gain for the circuit, device or system.

For example, another application for using AGC 200 may be monitoring of a phase in a power grid, as the monitored signals may also correspond a sine/cosine of the phase.

AGC 200 may comprise a sinewave generator module 202. Instead of using complex operations in the analog domain to determine the amplitude for RX_sin and RX_cos, a sinusoidal signal over time is generated based on RX_sin and RX_cos to efficiently extract the amplitude of RX_sin and RX_cos, i.e. to determine the value of A, when RX_sin=A*sin(ϕ) and RX_cos=A*cos(ϕ) with ϕ being the measured angle. Analogous equations for RX_sin and RX_cos may be determined for other types of measurement parameters. Sinewave generator module 202 may receive RX_sin and RX_cos and may generate an approximated sinusoidal signal over time. In particular, the approximated sinusoidal signal over time may be generated by determining a value of a shifted sine function at a plurality of sampling points. The approximated sinusoidal signal over time may be a step function. The shifted sine function may have a first frequency, which may be a design parameter. Notably, the phase shift and amplitude of the shifted sine function may depend on RX_sin and RX_cos. In other words, the sine wave generator module 202 may aim at generating a shifted sine function, with a shift corresponding to the argument of RX_sin and RX_cos, e.g. the angle ϕ, and an amplitude corresponding to the amplitude scaling factor A in RX_sin and RX_cos. A particularly efficient implementation of performing this sine wave generation over time will be presented further below.

While the angle ϕ may change constantly, e.g., when target 8 in the sensor is rotating constantly, accelerates or decelerates, ϕ may be assumed to be constant or quasi-constant during the generating of the approximated sinusoidal signal over time, e.g. during one period of the approximated sinusoidal signal over time. For this assumption to hold, a frequency of the approximated sinusoidal signal over time may have to be much higher than a rotation frequency of target 8, e.g., 100 times higher than the rotation frequency. Target 8 may also not rotate constantly but may stay at a particular position for a certain time, i.e., ϕ may not change over a certain time period.

By generating an approximated sinusoidal signal over time with an amplitude corresponding to the amplitude scaling factor A in RX_sin and RX_cos, A can be determined efficiently and accurately. The determination of A may be performed by gain control signal generator module 204. Gain control signal generator module 204 may generate a signal based on the approximated sinusoidal signal over time output by the sinewave generator module 202. In particular, the signal output by gain control signal generator module 204 may be proportional to the amplitude (e.g., magnitude) of an amplitude spectrum of the approximated sinusoidal signal over time at the first frequency, i.e., the frequency that was the target frequency for generating the approximated sinusoidal signal over time. Therefore, the signal output by gain control signal generator module 204 may be proportional to the scaling factor A in RX_sin and RX_cos, and may thus be suitable for a gain control signal for the circuit for measuring the measured parameter. The signal output by gain control signal generator module 204 may be used for gain control of the measurement circuit. How this signal is used for gain control may depend on particular implementations. The output signal of AGC 200 may be an analog signal. Without intended limitation, the output signal may further correspond to a voltage. The signal output by gain control signal generator module 204 may be further processed to generate a control signal that can be directly used for gain control of the measurement circuit. AGC 200 may therefore be connected to the circuit that processes the signals of the sensor, by receiving the demodulated output signals of the circuit and by providing the signal for controlling the gain of the circuit.

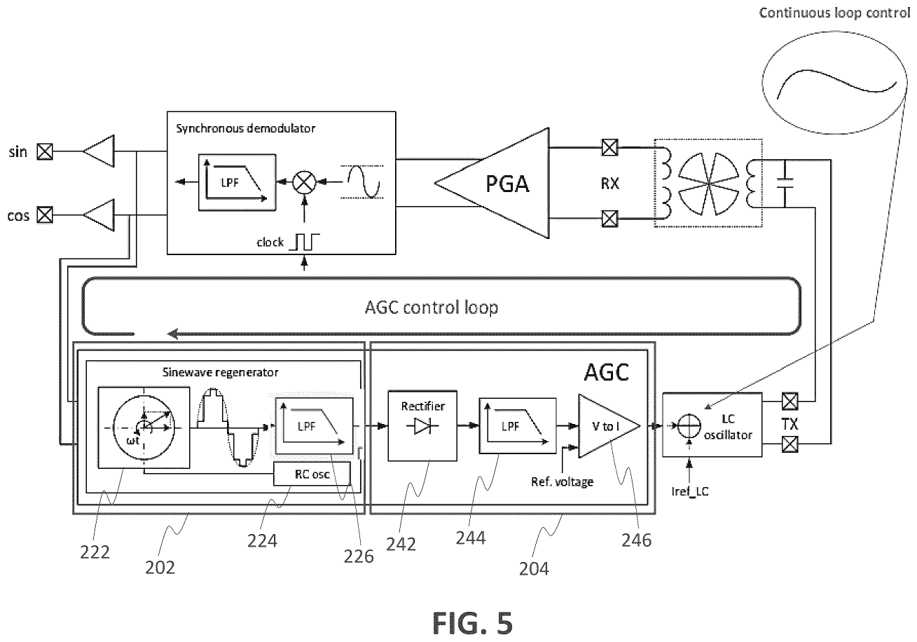

FIG. 5 depicts an example implementation of AGC 200 together with the measurement circuit according to embodiments of disclosure. Sinewave generator module 202 may comprise a sinewave generator 222 that receives an input signal by an RC oscillator 224. The input signal from RC oscillator 224 may be used to determine a phase of the sine wave for a sample point. As already mentioned above, the aim of the sinewave generator module 202 may be the generation of a sinusoidal function over time with a phase shift corresponding to an argument of RX_sin and RX_cos and an amplitude corresponding to the scaling factor of RX_sin and RX_cos.

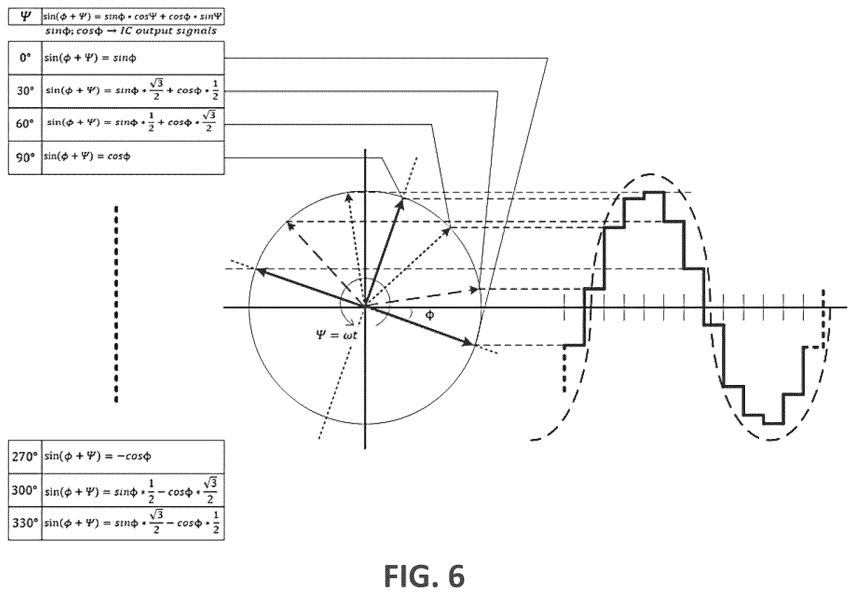

To illustrate the construction of the approximated sinewave over time, FIG. 6 depicts an example for the approximated sinewave function according to embodiments of this disclosure.

In this example, the sample points are chosen such that the distance between two sample points corresponds to a 30° shift (i.e., π/6). To summarize, the aim of the sinewave generator module 202 may be the generation of the function A*sin(ϕ+ψ), wherein ψ=ωt, with ω being the angular frequency and t being the sample points in time. As already mentioned, in FIG. 6, ωt is chosen such that the distance between two angles, corresponding to two sample points is equal to 30° (i.e., π/6).

Through use of the well-known trigonometric identity sin(a+b)=sin a cos b+cos a sin b, the value of A*sin(ϕ+ψ) can be determined by simple summations of scaled sin(ϕ) and cos(ϕ) terms. In the case of evaluation at multiples of 30°, only three values need to be determined beforehand for the scaling of sin(ϕ) and cos(ϕ) namely

$$1 , \frac{\sqrt{3}}{2} , and \frac{1}{2} .$$

As the generation of the approximated sinewave amounts to pure scaling and summation of the two input signals RX_sin and RX_cos(and possibly, their negatives), the generation of the signal can be implemented very efficiently in the analog domain.

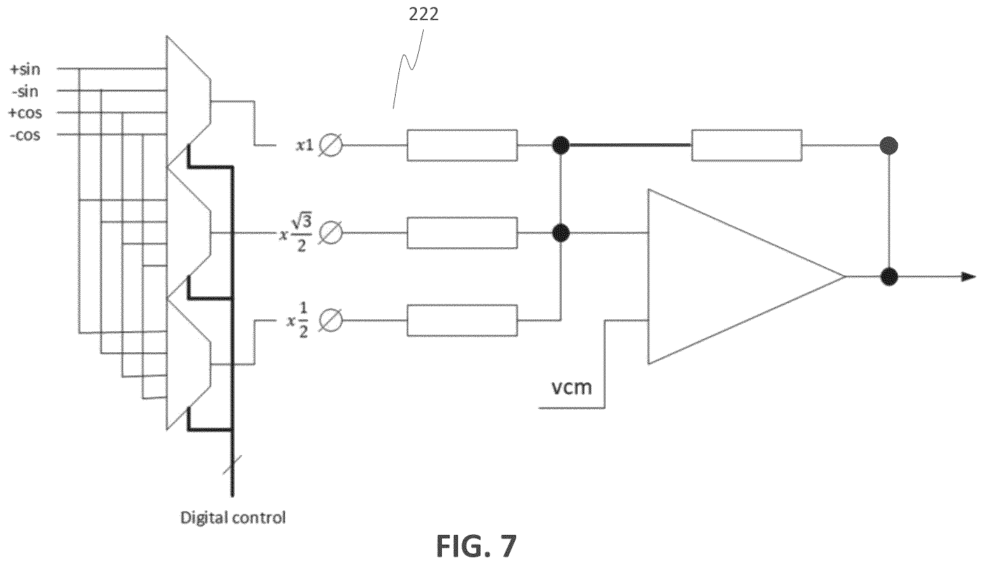

FIG. 7 depicts an example implementation for generating the approximated sinewave over time according to embodiments of this disclosure. In this example, sinewave generator 222 comprises a multiplexing module and a summation module. The summation module may comprise an analog summator with a feedback resistor, for example. For the implementation with 30° distance between the sampled angles, only three multiplexers for the multiplexing module and three multiplicators are needed for the summation module. The multiplexers are digitally controlled and have positive and negative (e.g., inverted) versions of RX_sin and

RX_cos as the inputs, so that each multiplexer can output the needed signal to the multiplicator for a particular sample point. For example, for a sample point corresponding to an angle of 30°, the first multiplexer outputs a zero signal (not shown in FIG. 7), the second multiplexer outputs sin(ϕ) and the third multiplexer outputs cos(ϕ). Then the three scaled versions of RX_sin and RX_cos are summed up. As one signal is zero (zero signal), merely two signals have to be summed up. In the particular implementation with 30° distance between the sampled angles, one or two signals will be zero depending on the angle used for determining the sinewave function. Therefore, only one or two signals need to be summed up for each sample point. In this way, the generation of an approximated sinewave over time with an argument of RX_sin and RX_cos and an amplitude corresponding to the scaling factor of RX_sin and RX_cos can be efficiently implemented by an analog summator.

The specific example with 30° distance between the sample angles should however not be construed as a limitation for the disclosure. The sinewave generation may be implemented with any distance between sampling points as long as the Nyquist Criterion is fulfilled. In other words, the frequency of the sampling points may need to be twice as high as the target frequency of the generated sine wave. Specific choices for the sampling points, e.g. 30° of the corresponding angle, may however be implemented more efficiently.

Returning to FIG. 5, the approximated sinewave function over time may need to be smoothed in order for gain control signal generator module 204 to be able to extract the amplitude of the sinewave. This functionality may be implemented by a smoothing module of the sinewave generate module 202. In the example of FIG. 5, the smoothing module may comprise a low-pass filter 226 with a cut-off frequency corresponding to or close to (e.g., slightly above) the first harmonic of the approximated sinewave function over time, i.e., the frequency corresponding to the angular frequency ω used for generation of the approximated sinewave function over time.

The output of sinewave generator module 202 may therefore be a smooth sinewave function over time with an amplitude corresponding to the scaling factor of input signals RX_sin and RX_cos.

Gain control signal generator module 204 may comprise an AC-DC converter module for determining the amplitude of a sinewave function. In the example of FIG. 5, the AC-DC converter module may comprise a rectifier 242 and a second low-pass filter 244. Rectifier 242 may be a full wave rectifier and the second low-pass filter 244 may have cut-off frequency such that only the DC value of the rectified sinewave function over time is allowed to pass.

By performing an AC-DC conversion of the generated sinewave function over time, the output signal will have an amplitude that is proportional to the scaling factor of RX_sin and RX_cos, i.e. proportional to A. In the above-described example for the AC-DC converter, the output signal may correspond to

$$A * \frac{2}{π} .$$

In an alternative implementation with a half wave rectifier instead of a full wave rectifier, the output signal may correspond to A/π.

The output signal indicative of the amplitude may then be used in various ways to control the amplification or attenuation in the circuit for measuring the measured parameter. In the non-limiting example of FIG. 5, the generated DC signal, i.e., the voltage signal proportional to the scaling factor in RX_sin and RX_cos, is used to directly steer the amplitude of the LC oscillator used for generating the excitation signal for the different transformer. To accomplish this, the DC output signal of low-pass filter 244 is compared to a reference voltage to generate an error signal. The reference voltage may depend on a desired value range for the output voltage of the circuit for measuring the measured parameter. The error signal may then be used to control the LC oscillator. In the example of FIG. 5, LC oscillator is current-driven, therefore the error signal is converted to a current signal by V to I converter 246. Therefore, a control signal corresponding to a DC current is output by gain control signal generator module 204. The DC current output is an input of the LC oscillator, together with a reference current signal. The reference current signal may correspond to a basis value for steering the amplitude of the LC oscillator. Therefore, the amplitude of the excitation signal for the differential transformer may be increased or decreased based on the DC output current signal of AGC 200.

In an alternative implementation, LC oscillator may be voltage driven. In this case, no voltage to current conversion element is needed.

In the example of FIG. 5, an amplitude corresponding to a scaling factor in the signal output by the two receiving coils of the differential transformer can be determined in the analog domain without complex mathematical operations. Further, the gain is not controlled via a discrete signal input to the PGA, but with a continuous signal input to the LC oscillator. Notably, the PGA can have a fixed gain or may be replaced by a different fixed gain element. Thereby, jumps and discontinuities in the output signal can be avoided.

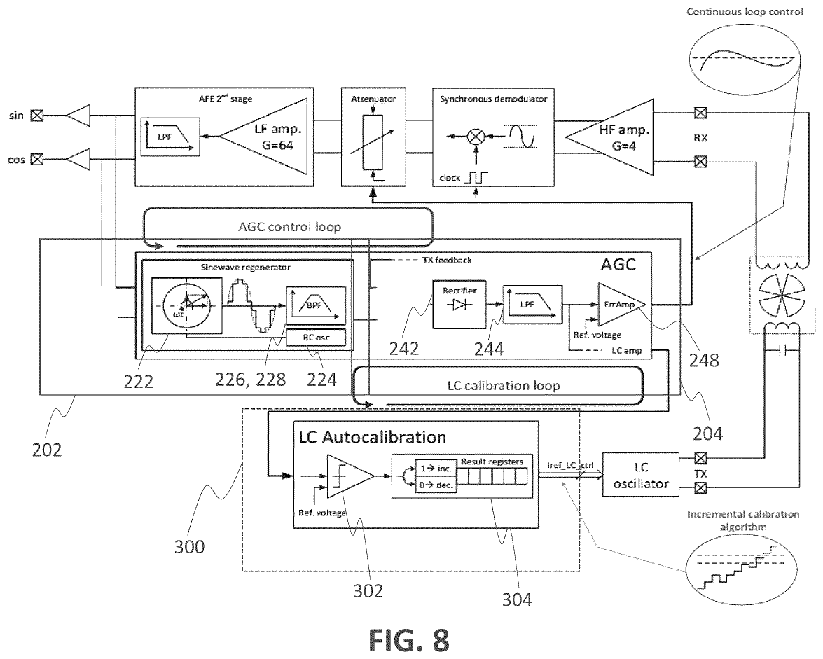

A downside of the implementation of AGC 200 in FIG. 5 may be a limited amount of gain control, as only the input/excitation signal can be controlled. For applications and use cases that require a greater range for gain control, FIG. 8 depicts a different implementation of AGC 200 according to embodiments of the disclosure. In particular, AGC 200 may use the same blocks as in FIG. 5 to generate the DC output voltage signal, i.e. the output of low-pass filter 244, but may use the output signal for a different control element in the circuit for measuring the measured parameter. In particular, the DC output voltage signal may be input of an error amplifier ErrAmp 248. ErrAmp 248 compares the DC output voltage signal to a reference voltage and determines the difference, i.e., the error signal. The reference voltage may correspond to a desired value range for the output signals of the circuit for measuring the measured parameter, i.e. RX_sin and RX_cos. Contrary to the implementation in FIG. 5, the error signal may then be used as the input for an analog gain element in the circuit for measuring the measured parameter. In other words, the analog gain element may attenuate or amplify the output signal of the two receiver coils of the differential amplifier based on the error signal.

The position of the analog gain element in the circuit for measuring the measured parameter in FIG. 8 merely serves as an example and is not intended to limit the disclosure. For instance, the analog gain element may also be positioned in front of the synchronous demodulator in FIG. 8, or may apply a gain directly to the demodulated output signals. In other words, the analog gain element may be positioned in a high frequency part or a low frequency part or anywhere between these parts in the signal chain of the measured parameter. The analog gain element may be implemented as an attenuator, if a constant amplification is additionally applied to the output signals of the two receiver coils (e.g., a high frequency amplifier and a low frequency amplifier).

Optionally, the DC output voltage signal of the low-pass filter may be used for calibration of the LC oscillator via LC calibration module 300. LC calibration module 300 may comprise a comparison module 302 and a digital output module 304. Comparison module 302 may compare the DC output voltage signal to a reference voltage. The reference voltage may be based on a desired value or value range for the output signals of the two receiver coils of the differential transformer. Based on the comparison, comparison module 302 outputs a signal for decrementing or incrementing a digital signal in the digital output module 304. Digital output module 304 may output the generated discrete signal for controlling an amplitude output by the LC oscillator. Notably, in some implementations, calibration of the LC oscillator via LC calibration module 300 may only be used during startup of circuit for measuring the measured parameter, in particular if circuit resources are shared between AGC 200 and LC calibration module 300. By using LC calibration module 300, a value range at the output of the two receiver coils may be ensured to be already closer to a desired value range, for example to account for value drifts induced by ageing effects and the like.

A further requirement for AGC 200 may be stability over a certain temperature range, as temperature-induced component value drift may have an impact on the precision of the determined amplitude for controlling the gain.

Here, temperature-induced component value drift may refer to the phenomenon where the electrical resistance of a material changes due to variations in temperature. This drift is a critical consideration in the design and operation of circuits processing sensor signals, as it can affect accuracy and reliability of the sensors. A component with a temperature induced value drift may be a resistor, a capacitance or an inductance, depending on the implemented circuit configuration. In particular, the value drift of the components in AGC 200 may lead to variations in the determined amplitude by up to 25% in some cases. Therefore, it may be advantageous to implement counter measures for the temperature induced drift, such that AGC 200 can be used reliably over a large temperature range.

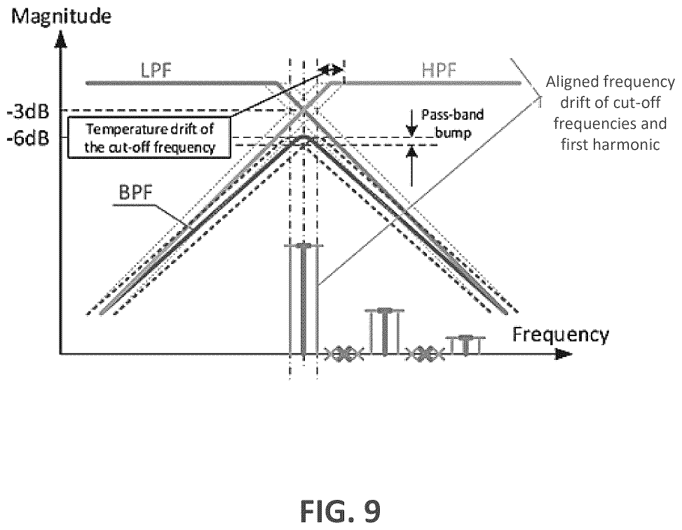

To achieve this, a high-pass filter 228 may be used for smoothing the approximated sinewave function over time in addition to low-pass filter 226. High-pass filter 228 is depicted in FIG. 8 as part of a band-pass filter. Low-pass filter 226 and high-pass filter 228 may alternatively be implemented separately. High-pass filter 226 may also have a cut-off frequency corresponding to or close to the angular frequency ω. By using the combination of a low-pass filter and high-pass filter, unwanted frequencies other than the first harmonic may be still effectively attenuated even when the cut-off frequencies are shifted due to the temperature-induced value drift. An example of the combination of the low-pass filter and the high-pass filter is depicted in FIG. 9, together with the amplitude spectrum of the approximated sinewave function over time. Using the band-pass filter for smoothing the approximated sinewave function over time may reduce variations of the estimated amplitude to about 2.5% over the temperature range.

The accuracy of AGC 200 may yet be further improved by considering the temperature induced drift of the cut-off frequencies when generating the approximated sinewave function over time. In particular, the angular frequency ω may be shifted by a drift adaptation module in a direction corresponding to the drift of the cut-off frequencies of the low-pass and high-pass filters. The shift of the angular frequency ω may be achieved by adapting a clock signal for AGC 200, e.g., by adapting a clock signal for RC oscillator 224. Therefore, the drift adaptation module may be implemented as an adaptation of the clock signal. By shifting the first harmonic of the approximated sinewave function over time (along with angular frequency ω) in the same direction as the temperature induced drift of the cut-off frequencies of the low-pass and high-pass filters, variations of the estimated amplitude may be reduced below 1.5% over the temperature range. The shift of the first harmonic and the cut-off frequencies is also depicted in FIG. 9.

By combining the previously mentioned concepts in AGC 200, an efficient determination of the amplitude/scaling factor of the output signals of the receiver coils, stability over a certain temperature range, and continuous gain adaptation can be achieved.

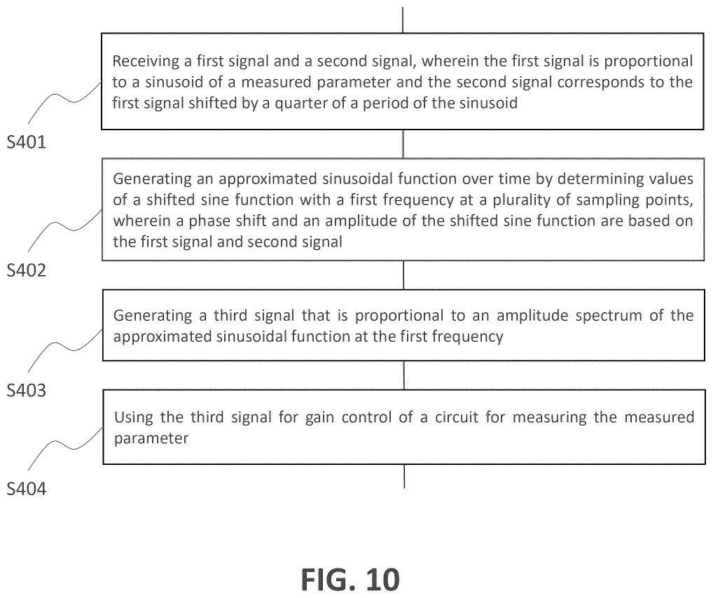

In line with the above, a method 400 is provided for automatic gain control as depicted in the flowchart of FIG. 10 In addition to the following method steps, method 400 may optionally include all variations described above with respect to the afore-mentioned AGC 200 that has been described in connection with FIGS. 4-9.

In step S201, a first signal and a second signal are received. The first signal is proportional to a sinusoid of a measured parameter (e.g., angular displacement or linear transitional displacement of a target) and the second signal corresponds to the first signal shifted by a quarter of a period of the sinusoid (e.g., by) 90°. For example, the first signal may be proportional to a sine of the measured parameter and the second signal may be proportional to the cosine of the measured parameter.

In step S202, an approximated sinusoidal function over time is generated. The approximated sinusoidal function over time is generated by determining values of a shifted sine function with a first frequency at a plurality of sampling points. A phase shift and an amplitude of the shifted sine function are based on the first signal and second signal. For example, the phase shift may be based on the measured parameter in the first signal and second signal.

In step S203, a third signal that is proportional to an amplitude spectrum of the approximated sinusoidal function at the first frequency is generated. In other words, the third signal may correspond or may be proportional to an amplitude of the first harmonic of the approximated sinusoidal function over time.

In step S204, the third signal is used for gain control of a circuit for measuring the measured parameter. Using the third signal for gain control may be accomplished by comparing the third signal to a reference value and using the result to steer an element capable of adjusting a gain in the circuit for measuring the measured parameter.

While this specification contains many specific implementation details, these should not be construed as limitations on the scope of any inventions or of what may be claimed, but rather as descriptions of features specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Unless specifically stated otherwise, as apparent from the following discussions, it is appreciated that throughout the present invention discussions utilizing terms such as “processing”, “computing”, “calculating”, “determining”, “analyzing” or the like, refer to the action and/or processes of a computer or computing system, or similar electronic computing devices, that manipulate and/or transform data represented as physical, such as electronic, quantities into other data similarly represented as physical quantities.

Reference throughout this invention to “one example embodiment”, “some example embodiments” or “an example embodiment” means that a particular feature, structure or characteristic described in connection with the example embodiment is included in at least one example embodiment of the present invention. Thus, appearances of the phrases “in one example embodiment”, “in some example embodiments” or “in an example embodiment” in various places throughout this invention are not necessarily all referring to the same example embodiment. Furthermore, the particular features, structures or characteristics may be combined in any suitable manner, as would be apparent to one of ordinary skill in the art from this invention, in one or more example embodiments.

As used herein, unless otherwise specified the use of the ordinal adjectives “first”, “second”, “third”, etc., to describe a common object, merely indicate that different instances of like objects are being referred to and are not intended to imply that the objects so described must be in a given sequence, either temporally, spatially, in ranking, or in any other manner.

Also, it is to be understood that the phraseology and terminology used herein are for the purpose of description and should not be regarded as limiting. The use of “including,” “comprising,” or “having” and variations thereof are meant to encompass the items listed thereafter and equivalents thereof as well as additional items. Unless specified or limited otherwise, the terms “mounted”, “connected”, “supported”, and “coupled” and variations thereof are used broadly and encompass both direct and indirect mountings, connections, supports, and couplings.

In the claims below and the description herein, any one of the terms comprising, comprised of or which comprises is an open term that means including at least the elements/features that follow, but not excluding others. Thus, the term comprising, when used in the claims, should not be interpreted as being limitative to the means or elements or steps listed thereafter. For example, the scope of the expression a device comprising A and B should not be limited to devices consisting only of elements A and B. Any one of the terms including or which includes or that includes as used herein is also an open term that also means including at least the elements/features that follow the term, but not excluding others. Thus, including is synonymous with and means comprising.

It should be appreciated that in the above description of example embodiments of the present invention, various features of the present invention are sometimes grouped together in a single example embodiment, Fig., or description thereof for the purpose of streamlining the present invention and aiding in the understanding of one or more of the various inventive aspects. This method of invention, however, is not to be interpreted as reflecting an intention that the claims require more features than are expressly recited in each claim. Rather, as the following claims reflect, inventive aspects lie in less than all features of a single foregoing disclosed example embodiment. Thus, the claims following the Description are hereby expressly incorporated into this Description, with each claim standing on its own as a separate example embodiment of this invention.

Furthermore, while some example embodiments described herein include some but not other features included in other example embodiments, combinations of features of different example embodiments are meant to be within the scope of the present invention, and form different example embodiments, as would be understood by those skilled in the art. For example, in the following claims, any of the claimed example embodiments can be used in any combination.

In the description provided herein, numerous specific details are set forth. However, it is understood that example embodiments of the present invention may be practiced without these specific details. In other instances, well-known methods, structures and techniques have not been shown in detail in order not to obscure an understanding of this description.

Thus, while there has been described what are believed to be the best modes of the present invention, those skilled in the art will recognize that other and further modifications may be made thereto without departing from the spirit of the present invention, and it is intended to claim all such changes and modifications as fall within the scope of the present invention. For example, any formulas given above are merely representative of procedures that may be used. Functionality may be added or deleted from the block diagrams and operations may be interchanged among functional blocks. Steps may be added or deleted to methods described within the scope of the present disclosure.

1. An apparatus for automatic gain control, the apparatus comprising:
a sinewave generator module; and
a gain control signal generator module;
wherein the sinewave generator module is configured to receive a first signal and a second signal, wherein the first signal is proportional to a sinusoid of a measured parameter and the second signal corresponds to the first signal shifted by a quarter of a period of the sinusoid;
the sinewave generator module is further configured to generate an approximated sinusoidal function over time by determining values of a shifted sine function with a first frequency at a plurality of sampling points, wherein a phase shift and an amplitude of the shifted sine function are based on the first signal and second signal;
the gain control signal generator module is configured to generate a third signal that is proportional to an amplitude spectrum of the approximated sinusoidal function at the first frequency; and
the gain control signal generator module is further configured to output the third signal to a circuit for measuring the measured parameter, wherein the apparatus for automatic gain control is connected to the circuit and the third signal is used for gain control of the circuit.

2. The apparatus of claim 1, wherein the first signal, the second signal and the third signal are analog signals.

3. The apparatus of claim 1, wherein the sinewave generator module is configured to perform linear operations in the analog domain.

4. The apparatus of claim 1, wherein the first signal is proportional to sin(x) and the second signal is proportional to cos(x), wherein x is the measured parameter.

5. The apparatus of claim 4, wherein the first signal is equal to A*sin(x) and the second signal is equal to A*cos(x), wherein A depends on an excitation signal for the circuit for measuring the measured parameter and a sensor configuration for measuring the measured parameter.

6. The apparatus of claim 1, wherein determining values of the shifted sine function with a first frequency at a plurality of sampling points comprises:
for each value and a corresponding sampling point:
the sinewave generator module is configured to summate weighted versions of the first signal and the second signal, wherein weights of the weighted versions of the first and the second signal correspond to a sine function and cosine function evaluated at a first angle, wherein the first angle is based on the sampling point and the first frequency.

7. The apparatus of claim 6, wherein the sinewave generator module comprises:
a multiplexing module; and
a summation module;
wherein the multiplexing module is configured to determine a plurality of fourth signals by multiplexing positive and negative versions of the first signal and the second signal, and a zero signal;
the summation module is configured to multiply each of the plurality of fourth signals with a different weight of the weights to generate weighted versions of the plurality of fourth signals; and
the summation module is further configured to summate the weighted versions of the plurality of fourth signals to generate a value of the shifted sine function at the sampling point.

8. The apparatus of claim 7, wherein the plurality of fourth signals and weights for each of the plurality of fourth signals are chosen for each sampling point such that the shifted sine function with the first frequency and with an amplitude of A is approximated.

9. The apparatus of claim 7, wherein a number of the plurality of fourth signals is 1 or 2.

10. The apparatus of claim 1, wherein the weights are 1, \sqrt{3}/2 and ½.

11. The apparatus of claim 7,
wherein the sinewave generator module further comprises a smoothing module;
and the smoothing module is configured to generate a sinusoidal function over time by smoothing the approximated sinusoidal function;
the gain control signal generator module comprises an AC-DC converter module; and
the AC-DC converter module is configured to generate the third signal from the sinusoidal function.

12. The apparatus of claim 1, wherein the smoothing module comprises a second low-pass filter configured to generate the sinusoidal function over time by filtering the approximated sinusoidal function; and
wherein the smoothing module further comprises a high-pass filter; and
the high-pass filter is configured to operate together with the second low-pass filter to generate the sinusoidal function over time by smoothing the approximated sinusoidal function.

13. The apparatus of claim 12, wherein the apparatus further comprises a drift adaptation module,
the drift adaptation module is configured to adapt the first frequency to match a temperature induced drift of the cut-off frequency of the first second-pass filter or/and the high-pass filter.

14. The apparatus of claim 1, wherein the gain control signal generator module comprises an error signal generator module;
the error signal generator module is configured to generate an error signal by comparing the third signal to a first reference value;
the error signal generator module is further configured to output the error signal to the circuit for measuring the measured parameter, wherein the error signal is used for gain control of the circuit.

15. The apparatus of claim 14, wherein using the error signal for gain control of the circuit for measuring the measured parameter comprises:
controlling an LC oscillator with the error signal, wherein the LC oscillator is part of the circuit for measuring the measured parameter and configured to provide an excitation signal.

16. The apparatus of claim 14, wherein using the error signal for gain control of the circuit for measuring the measured parameter comprises:
controlling an analog gain element in the circuit for measuring the measured parameter with the error signal.

17. The apparatus of claim 16, wherein the apparatus further comprises an LC calibration module;
the LC calibration module is configured to calibrate an LC oscillator based on the third signal, wherein the LC oscillator provides an excitation signal for the circuit for measuring the measured parameter.

18. The apparatus of claim 17, wherein the LC calibration module comprises:
a comparison module; and
a digital output module;
wherein the comparison module is configured to compare the third signal to a second reference value;
based on a result of the comparison, the digital output module is configured to increment or decrement a digital signal; and
the digital output module is further configured to output the digital signal for controlling the LC oscillator.

19. A measurement circuit with automatic gain control, comprising:
the apparatus for automatic gain control according to claim 1; and
a circuit for measuring a measured parameter, wherein the circuit is connected to the apparatus for automatic gain control.

20. A method for automatic gain control, the method performing gain control with an apparatus according to claim 1.
